(19) United States
(12) Patent Application Publication
(10) Pub. No.: US 2026/0089926 A1
(43) Pub. Date: Mar. 26, 2026

(54) SEMICONDUCTOR STRUCTURE AND MANUFACTURING METHOD THEREOF

(71) Applicant: NANYA TECHNOLOGY CORPORATION, New Taipei City (TW)

(72) Inventors: Ji-Feng LIU, New Taipei City (TW); Chao-Hsiu LI, New Taipei City (TW)

(21) Appl. No.: 18/890,784

(22) Filed: Sep. 20, 2024

(51) Int. Cl. H10B 12/00

(52) U.S. Cl. CPC H10B 12/482; H10B 12/02

(57) ABSTRACT

A semiconductor structure includes a semiconductor substrate, a bit-line structure, and a bit-line spacer. The bit-line structure is disposed on the semiconductor substrate. The bit-line spacer covers the bit-line structure, in which the bit-line spacer includes a SiCO layer, an insulating oxide layer, and an insulating nitride layer. The SiCO layer covers the bit-line structure, in which an oxygen concentration of the SiCO layer is equal to or greater than 55 at %. The insulating oxide layer covers the SiCO layer. The insulating nitride layer covers the insulating oxide layer.

### BACKGROUND

### Field of Invention

The present disclosure relates to a semiconductor structure and a manufacturing method thereof.

### Description of Related Art

Dynamic random access memory (DRAM) devices are semiconductor arrangements for storing bits of data with cell capacitors within an integrated circuit. The DRAM devices commonly include trench capacitor DRAM cells and/or stacked capacitor DRAM cells. As DRAM devices become more highly integrated, components of the DRAM devices become finer. However, as the size of a DRAM device is reduced, the quality of components in the DRAM device may degrade. To overcome the performance issue, there is a significant need to improve the manufacturing process.

### SUMMARY

The present disclosure provides a semiconductor structure including a semiconductor substrate, a bit-line structure, and a bit-line spacer. The bit-line structure is disposed on the semiconductor substrate. The bit-line spacer covers the bit-line structure, in which the bit-line spacer includes a SiCO layer, an insulating oxide layer, and an insulating nitride layer. The SiCO layer covers the bit-line structure, in which an oxygen concentration of the SiCO layer is equal to or greater than 55 at %. The insulating oxide layer covers the SiCO layer. The insulating nitride layer covers the insulating oxide layer.

In some embodiments, the oxygen concentration of the SiCO layer is from 55 at % to 65 at %.

In some embodiments, a carbon concentration of the SiCO layer is from 5 at % to 12 at %.

In some embodiments, the SiCO layer has a thickness of 8 angstrom to 15 angstrom.

In some embodiments, the SiCO layer has a dielectric constant of 3.9 to 4.7.

In some embodiments, the insulating oxide layer has a thickness of 3.5 angstrom to 5 angstrom.

In some embodiments, the SiCO layer conformally covers a sidewall of the bit-line structure.

In some embodiments, the bit-line structure includes: a conductive silicon layer, a conductive layer disposed on the conductive silicon layer, and a hard mask layer disposed on the conductive layer.

In some embodiments, the SiCO layer is in direct contact with the bit-line structure.

In some embodiments, the insulating oxide layer is a silicon dioxide layer, and the insulating nitride layer is a silicon nitride.

In some embodiments, a density of the SiCO layer is 2.2 g/cm³ to 2.5 g/cm³.

The present disclosure provides a method of manufacturing a semiconductor structure, the method include the following operations. A bit-line structure is formed on a semiconductor substrate. A SiCO layer is formed to cover the bit-line structure, in which an oxygen concentration of the SiCO layer is equal to or greater than 55 at %. An insulating oxide layer is formed to cover the SiCO layer. An insulating nitride layer is formed to cover the insulating oxide layer.

In some embodiments, forming the SiCO layer includes reacting an oxygen gas and an alkyl siloxane to form the SiCO layer.

In some embodiments, a reaction temperature is 500° C. to 600° C.

In some embodiments, a flow rate of the oxygen gas is 75 sccm to 155 sccm.

In some embodiments, a flow rate of the alkyl siloxane is 54 sccm to 66 sccm.

In some embodiments, the alkyl siloxane includes 1,1,3,3-tetramethyldisiloxane.

In some embodiments, forming the SiCO layer is performed by remote plasma-enhanced atomic layer deposition (remote plasma-enhanced ALD) or plasma-enhanced chemical vapor deposition (PECVD).

In some embodiments, the method further includes the following operations. Before the insulating oxide layer is formed to cover the SiCO layer, a nitride layer is formed to cover the SiCO layer and to fill a plurality of trenches in the semiconductor substrate and next to the bit-line structure. The nitride layer is etched to expose a portion of the SiCO layer and leave portions of the nitride layer in the trenches by a wet etch solution.

In some embodiments, the wet etch solution includes H₃PO₄, NH₄OH, H₂O₂, and H₂O.

### BRIEF DESCRIPTION OF THE DRAWINGS

The present disclosure can be more fully understood by reading the following detailed description of the embodiments, with reference made to the accompanying drawings.

FIGS. 1-3 are schematic cross-sectional views illustrating intermediate stages of manufacturing a semiconductor structure according to comparative examples of the present disclosure.

FIG. 4 is a flowchart of a method of manufacturing a semiconductor structure according to various embodiments of the present disclosure.

FIGS. 5 to 11 are schematic cross-sectional views illustrating intermediate stages of manufacturing a semiconductor structure according to various embodiments of the present disclosure.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

The present disclosure provides a semiconductor structure and a manufacturing method thereof. The semiconductor structure includes a bit-line structure and a bit-line spacer covering the bit-line structure, in which the bit-line spacer includes a SiCO layer with an oxygen concentration equal to or greater than 55 at %. Due to the high oxygen concentration of the SiCO layer, it is possible to form a thin SiCO layer with a low dielectric constant and a high density, which is beneficial to reduce the size of the semiconductor structure and reduce the resistive-capacitive delay (RC delay). Moreover, since the SiCO layer can have the high density, pinholes are less likely to be found in the SiCO layer, and therefore the semiconductor structure can have good performance.

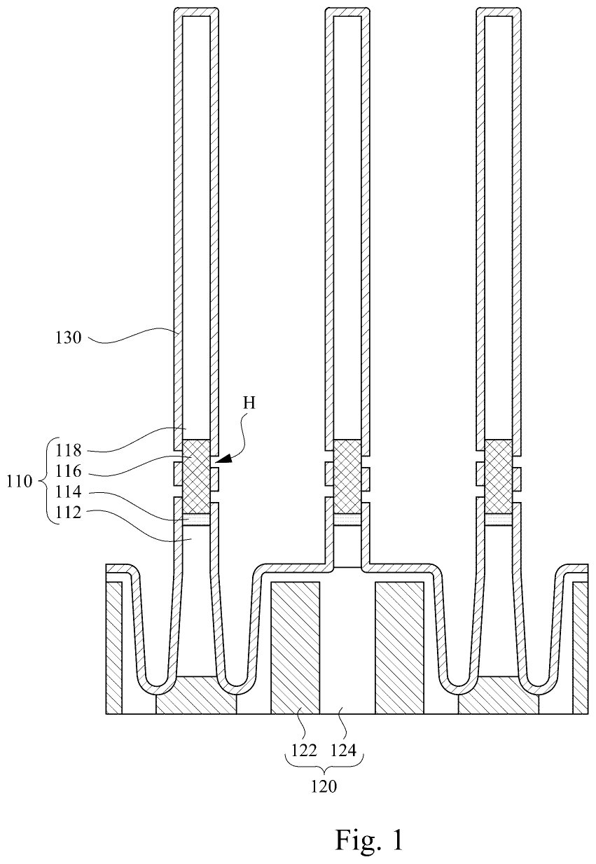

FIGS. 1-3 are schematic cross-sectional views illustrating intermediate stages of manufacturing a semiconductor structure according to comparative examples of the present disclosure.

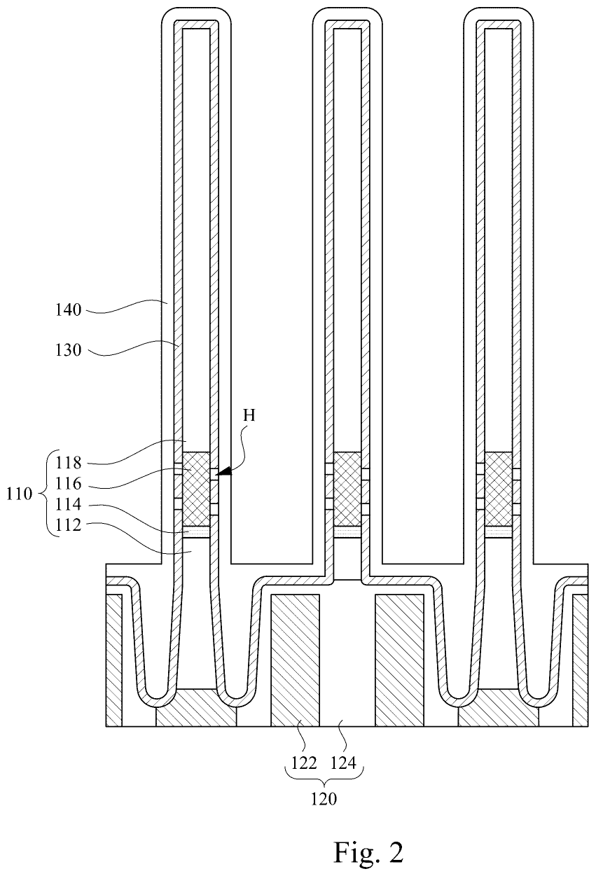

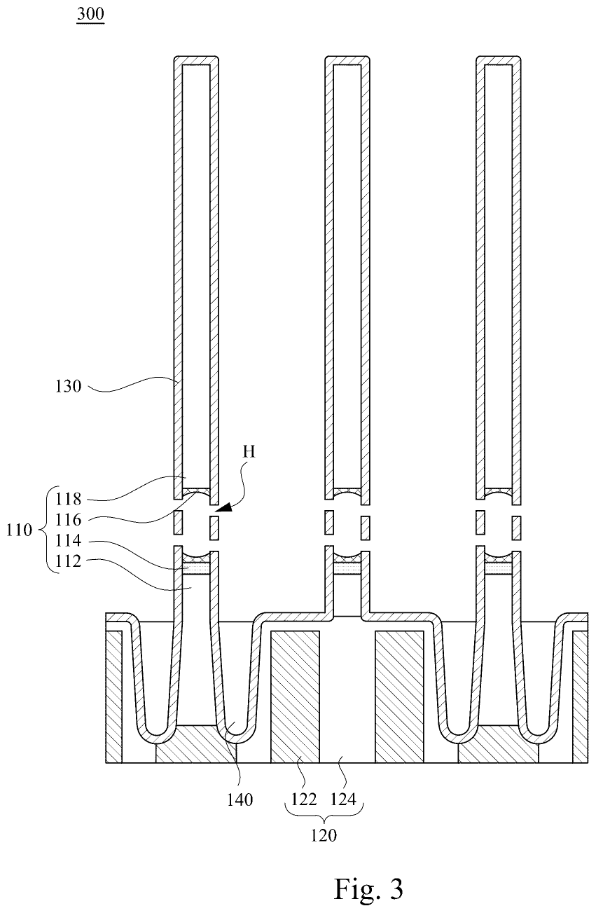

As shown in FIG. 1, a plurality of bit-line structures 110 is formed on a semiconductor substrate 120, and a SiCO layer 130 is formed to cover the bit-line structures 110. The semiconductor substrate 120 includes a substrate 122 and isolation regions 124 embedded in the substrate. Each of the bit-line structure 110 includes a conductive silicon layer 112, a barrier layer 114, a conductive layer 116, and a hard mask layer 118. If the thickness of the SiCO layer 130 is too thin, pinholes H may be easily formed in the SiCO layer 130, and therefore the conductive layers 116 of the bit-line structures 110 may be exposed through the pinholes H. Attention is now invited to FIG. 2. A nitride layer 140 is formed to cover the SiCO layer 130. Reference is made to FIG. 3. The nitride layer 140 is etched to expose portions of the SiCO layer 130 by a wet etch solution to form a semiconductor structure 300. As shown in FIG. 3, after the wet etch, because the conductive layers 116 (such as tungsten layers) of the bit-line structures 110 may be exposed through the pinholes H and therefore be damaged and removed by the wet etch solution, portions of the conductive layers 116 are missing, which reduces the resistance of the bit-line structures 110 and severely influence the RC delay performance. Therefore, the performance of the semiconductor structure 300 degrades.

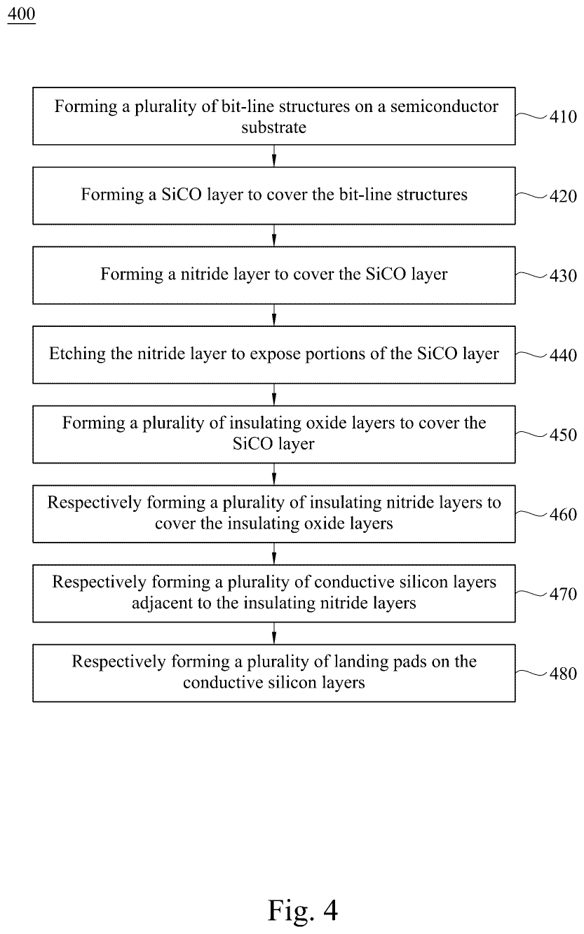

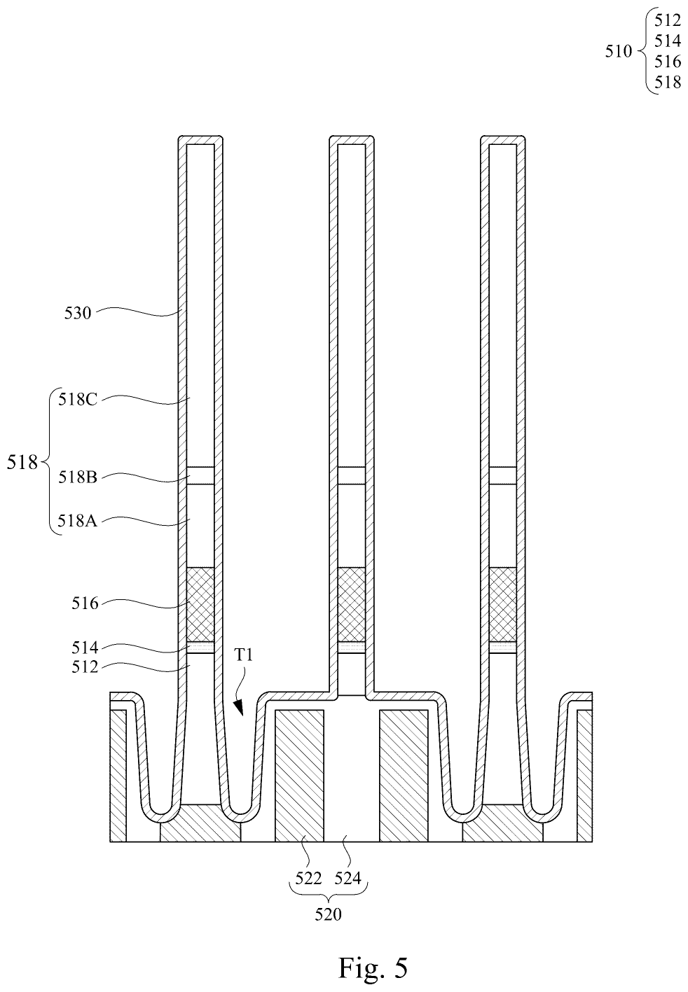

The present disclosure provides a manufacturing method of a semiconductor structure. Please refer to FIG. 4 and FIGS. 5-11. FIG. 4 is a flowchart of a method 400 of manufacturing a semiconductor structure according to various embodiments of the present disclosure. The method 400 includes operation 410, operation 420, operation 430, operation 440, operation 450, operation 460, operation 470, and operation 480. FIGS. 5 to 11 are schematic cross-sectional views illustrating intermediate stages of manufacturing a semiconductor structure according to various embodiments of the present disclosure. The above-mentioned operations 410 to 480 will be described later with FIGS. 5 to 11.

Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all of the operations, steps, and/or features shown to achieve the embodiments of the present disclosure. In addition, each operation or step described herein may contain several sub-steps or actions.

In operation 410, as shown in FIG. 5, a plurality of bit-line structures 510 is formed on a semiconductor substrate 520. More specifically, the semiconductor substrate 520 has a plurality of trenches T1, in which one of the bit-line structures 510 is formed on the upper surface of the semiconductor substrate 520, and two of the bit-line structures 510 are formed in the trenches T1 of the semiconductor substrate 520. It is noted that the number of bit-line structures 510 is exemplary and can be adjusted according to design requirements.

Please still refer to FIG. 5. The semiconductor substrate 520 includes a substrate 522 and isolation regions 524 embedded in the substrate 522. In some embodiments, the substrate 522 includes an elementary semiconductor, a compound semiconductor material, or an alloy semiconductor material. The elementary semiconductor includes a single crystal form, a polycrystalline form, or an amorphous form of silicon (Si) or germanium (Ge). The compound semiconductor material includes silicon carbide (SiC), gallium arsenide (GaAs), gallium phosphide (GaP), indium phosphide (InP), indium arsenide (InAs), indium antimonide (InSb), other suitable materials, or combinations thereof. The alloy semiconductor material includes silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), gallium indium arsenide phosphide (GaInAsP), other suitable materials, or combinations thereof. In some embodiments, the alloy semiconductor material includes silicon germanium (SiGe) with gradient Ge characteristics, in which the composition of Si and Ge changes from one ratio at one location of the gradient SiGe characteristics to another ratio at another location. In some embodiments, SiGe is formed on a Si substrate. In some embodiments, SiGe is mechanically strained by another material in contact with SiGe. In some embodiments, the isolation regions 524 are formed through a shallow trench isolation (STI) process. The isolation regions 524 may include, for example, silicon dioxide, silicon nitride, silicon oxynitride, or combinations thereof.

In some embodiments, each of the bit-line structures 510 includes a conductive silicon layer 512, a barrier layer 514, a conductive layer 516, and a hard mask layer 518. The barrier layer 514 is disposed on the conductive silicon layer 512. The conductive layer 516 is disposed on the barrier layer 514. The hard mask layer 518 is disposed on the conductive layer 516. In some embodiments, the conductive silicon layer 512 includes polysilicon. In some embodiments, the barrier layer 514 may be a single layer or multiple layers and includes a metal layer, a metal nitride layer, a metal silicide layer, or combinations thereof. The metal layer may include Co, Cu, Ni, Ru, Mn, Ag, Au, Pt, Fe, Mo, Rh, Ti, Ta, W, or combinations thereof. The metal nitride layer may include tungsten nitride, titanium nitride, tantalum mononitride, or combinations thereof. The metal silicide layer may include tungsten silicide, tantalum silicide, titanium silicide, molybdenum silicide, zirconium silicide, cobalt silicide, chromium silicide, nickel silicide, or combinations thereof. In some embodiments, the barrier layer 514 is omitted, and therefore the conductive layer 516 is disposed on and in direct contact with the conductive silicon layer 512. In some embodiments, the conductive layer 516 includes metal, such as W, Ru, Ir, Pt, Rh, Mo, or combinations thereof. In some embodiments, the hard mask layer 518 is a single layer or multiple layers. In some embodiments, the hard mask layer 518 includes an insulating material, such as Si₃N₄, SiCN, SiC, SiO₂, or combinations thereof. In some embodiments, the hard mask layer 518 includes an insulating nitride layer 518A, an insulating oxide layer 518B, and an insulating nitride layer 518C that are stacked. The insulating nitride layers 518A, 518C may include Si₃N₄, and the insulating oxide layer 518B may include SiO₂.

In operation 420, as shown in FIG. 5, a SiCO layer 530 is formed to cover the bit-line structures 510. More specifically, the SiCO layer 530 covers the top surfaces and the sidewalls of the bit-line structures 510, the sidewalls of the trenches T1, and the upper surface of the semiconductor substrate 520. In some embodiments, the SiCO layer 530 is in direct contact with the bit-line structures 510. In some embodiments, an oxygen concentration of the SiCO layer 530 is equal to or greater than 55 at %. In some embodiments, the oxygen concentration of the SiCO layer 530 is from 55 at % to 65 at %, such as 55, 56, 57, 58, 59, 60, 61, 62, 63, 64, or 65 at %. Due to the high oxygen concentration, it is possible to form the SiCO layer 530 with a thin thickness, a low dielectric constant, and a high density, which is beneficial to reduce the size of the semiconductor structure and reduce the RC delay. In some embodiments, a carbon concentration of the SiCO layer 530 is from 5 at % to 12 at %, such as 5, 6, 7, 8, 9, 10, 11, or 12 at %. In some embodiments, a density of the SiCO layer 530 is 2.2 g/cm³ to 2.5 g/cm³, such as 2.2, 2.3, 2.4, or 2.5 g/cm³. Since the SiCO layer 530 can have the high density, pinholes are less likely to be found in the SiCO layer 530, and therefore the SiCO layer 530 can protect the bit-line structures 510 during etching process.

Since the SiCO layer 530 of the present disclosure has the high oxygen concentration, its dielectric constant can be reduced and become similar to the dielectric constant of a SiO₂ layer (such as 3.9), which is beneficial to reduce the RC delay. In some embodiments, the SiCO layer 530 has a dielectric constant of 3.9 to 4.7, such as 3.9, 4.0, 4.1, 4.2, 4.3, 4.4, 4.5, 4.6, or 4.7. Furthermore, since the SiCO layer 530 of the present disclosure has the high oxygen concentration, the SiCO layer 530 can have an ultra-thin thickness and also have a low dielectric constant and a high density, which is beneficial to reduce the size of the semiconductor structure. In some embodiments, the SiCO layer 530 has a thickness of 8 angstrom to 15 angstrom, such as 8, 9, 10, 11, 12, 13, 14, or 15 angstrom.

Please still refer to FIG. 5. In some embodiments, forming the SiCO layer 530 is performed by remote plasma-enhanced atomic layer deposition (remote plasma-enhanced ALD) or plasma-enhanced chemical vapor deposition (PECVD). In some embodiments, the SiCO layer 530 conformally covers the bit-line structures 510. In some embodiments, forming the SiCO layer 530 includes reacting an oxygen gas and an alkyl siloxane to form the SiCO layer 530. In some embodiments, a reaction temperature is 500° C. to 600° C., such as 500, 510, 520, 530, 540, 550, 560, 570, 580, 590, or 600° C. When the reaction temperature is between 500° C. to 600° C., the SiCO layer 530 can have a high density, and therefore pinholes are less likely to be formed in the SiCO layer 530. In some embodiments, a flow rate of the oxygen gas is 75 sccm to 155 sccm, such as 75, 85, 95, 105, 115, 125, 135, 145, or 155 sccm. In some embodiments, a flow rate of the alkyl siloxane is 54 sccm to 66 sccm, such as 54, 56, 58, 60, 62, 64, or 66 sccm. In some embodiments, the alkyl siloxane includes 1,1,3,3-tetramethyldisiloxane. When the flow rates fall within the above ranges, the SiCO layer 530 can have a high oxygen concentration and a high density and therefore can have a better quality and a low dielectric constant.

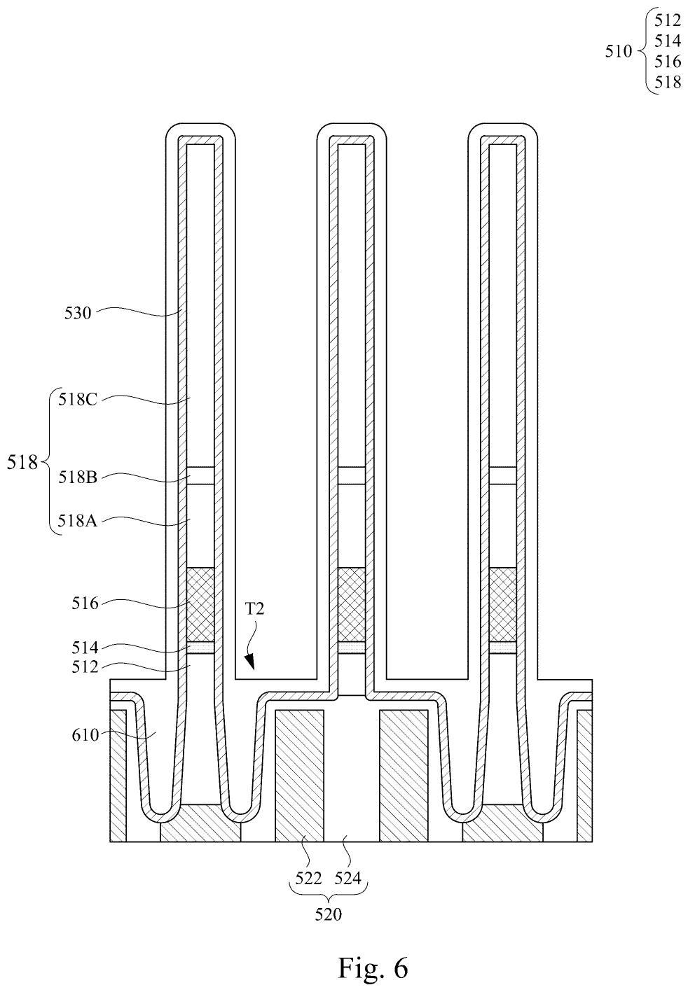

In operation 430, as shown in FIG. 6, a nitride layer 610 is formed to cover the SiCO layer 530. More specifically, the nitride layer 610 covers the SiCO layer 530 and fills the trenches T2 in the semiconductor substrate 520 and next to the bit-line structures 510. In some embodiments, the nitride layer 610 includes an insulating nitride material, such as Si₃N₄.

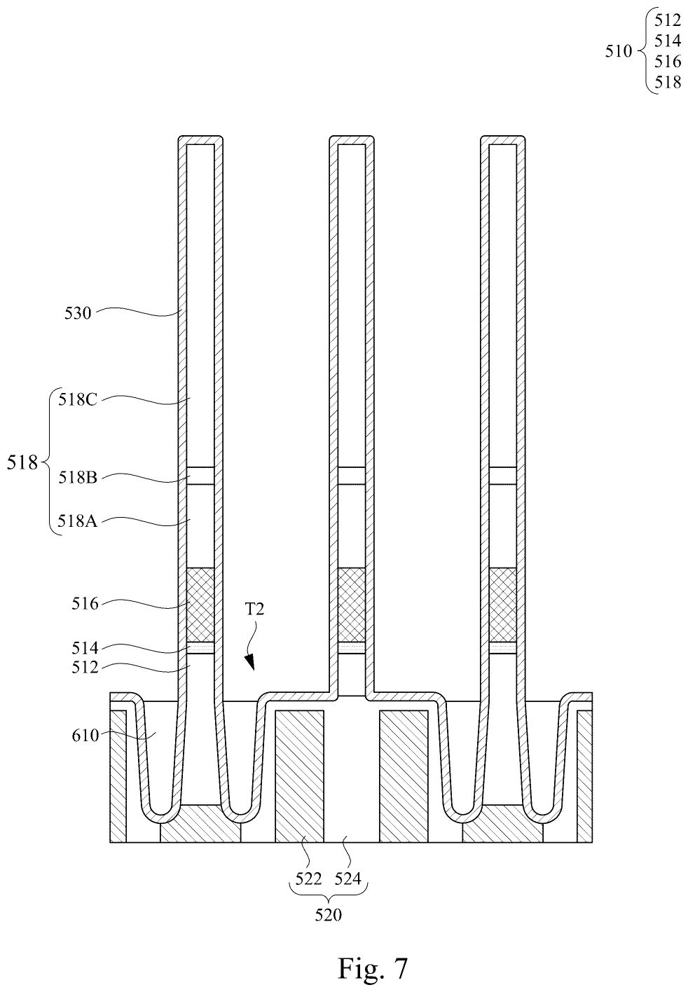

In operation 440, as shown in FIG. 7, the nitride layer 610 is etched to expose portions of the SiCO layer 530. More specifically, the nitride layer 610 is etched to leave portions of the nitride layer 610 in the trenches T2 and expose the portions of the SiCO layer 530 above the portions of the nitride layer 610. In some embodiments, the nitride layer 610 is etched by a wet etch solution. In some embodiments, the wet etch solution includes H₃PO₄, NH₄OH, H₂O₂, and H₂O. Since the SiCO layer 530 of present disclosure is formed under a higher temperature, such 500° C. to 600° C., the SiCO layer 530 can have a higher density, such as 2.2 g/cm³ to 2.5 g/cm³, which is beneficial to protect the bit-line structures 510 from being damaging by the wet etch solution. In other words, the SiCO layer 530 of present disclosure can have better etch resistance. Furthermore, sine the SiCO layer 530 has the higher density, pinholes are less likely to be found in the SiCO layer 530. Therefore, the conductive layers 516 of the bit-line structures 510 can be protected by the SiCO layer 530 without being damaging by the wet etch solution.

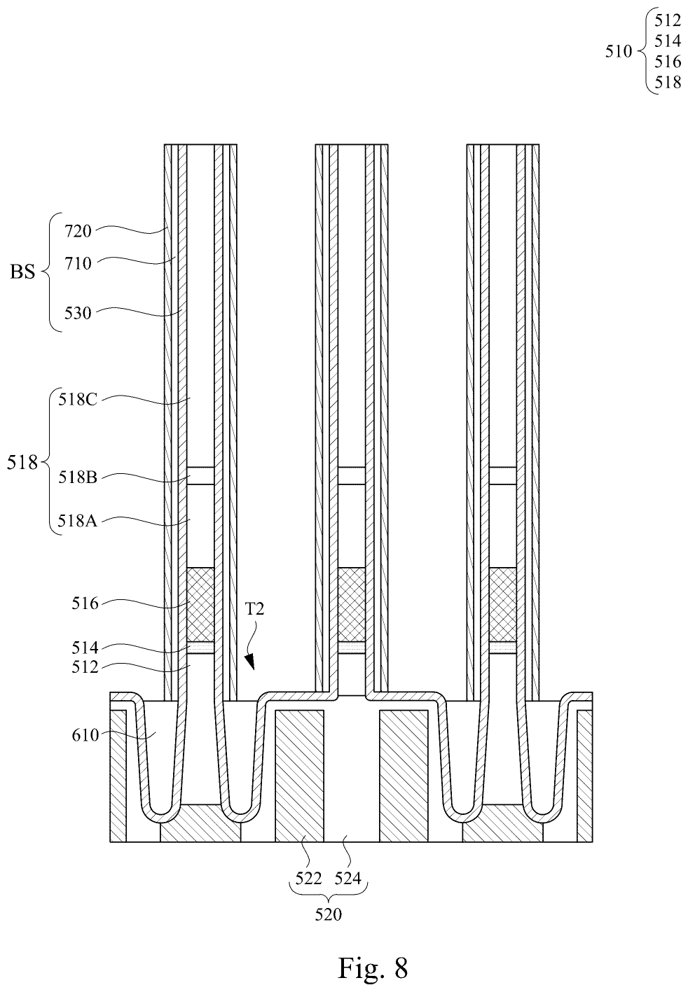

In operation 450, as shown in FIG. 8, a plurality of insulating oxide layers 710 is formed to cover the SiCO layer 530. More specifically, the insulating nitride layers 720 respectively cover the sidewalls of the SiCO layer 530. In some embodiments, the insulating oxide layers are silicon dioxide layers. In operation 460, as shown in FIG. 8, a plurality of insulating nitride layers is respectively formed to cover the insulating oxide layers 710. More specifically, the insulating nitride layers respectively cover the sidewalls of the insulating nitride layers 720. In some embodiments, the insulating nitride layers are silicon nitride layers.

Please still refer to FIG. 8. Each bit-line spacer BS includes the SiCO layer 530, the insulating oxide layer 710, and the insulating nitride layer 720. Since the SiCO layer 530 of the present disclosure can have a thin thickness, the thickness of the insulating oxide layers 710 can be increased to further reduce the dielectric constant of the bit-line spacers BS. In some embodiments, the insulating oxide layers respectively have a thickness of 3.5 angstrom to 5 angstrom, such as 3.5, 4, 4.5, or 5 angstrom.

Please still refer to FIG. 8. In some embodiments, the insulating oxide layers 710 and the insulating nitride layers 720 are formed by the following operations. An insulating oxide layer is formed to cover the SiCO layer 530 shown in FIG. 7. In some embodiments, the insulating oxide layer is formed by atomic layer deposition (ALD) or chemical vapor deposition (CVD). Next, an insulating nitride layer is formed to cover the insulating oxide layer. In some embodiments, the insulating nitride layer is formed by ALD or CVD. Subsequently, portions of the insulating oxide layer and the insulating nitride layer and top portions of the SiCO layer 530 are removed to form the bit-line spacers BS shown in FIG. 8. In some embodiments, the SiCO layer 530 conformally covers the sidewalls of the bit-line structures 510.

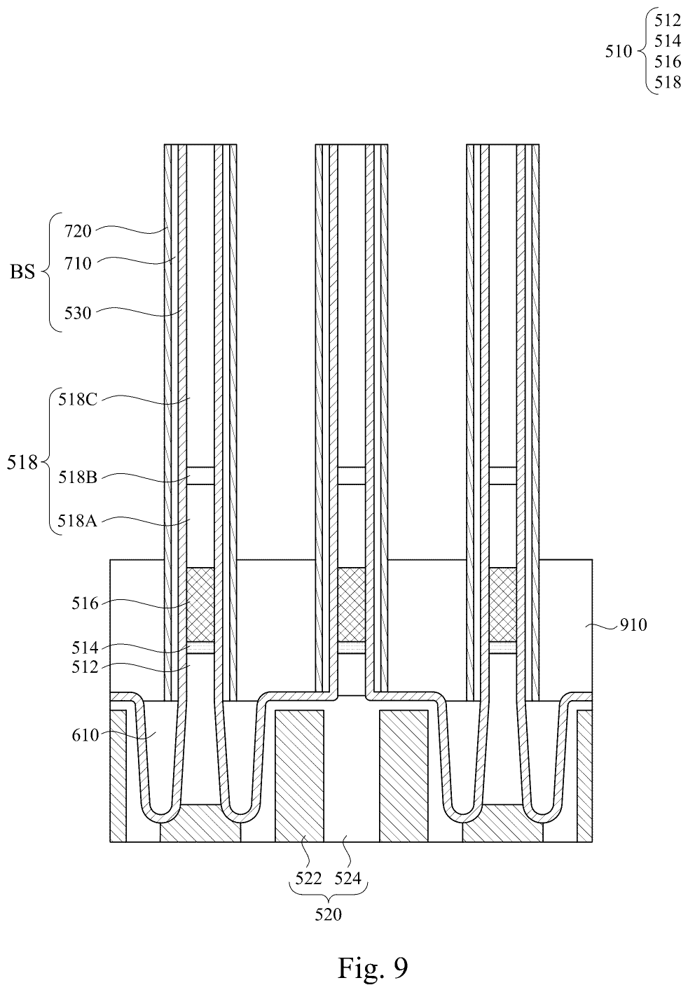

In operation 470, as shown in FIG. 9, a plurality of conductive silicon layers 910 is respectively formed adjacent to the insulating nitride layers 720. In some embodiments, the conductive silicon layers 910 include polysilicon. In some embodiments, the conductive silicon layers 910 are formed by CVD and an etch-back process.

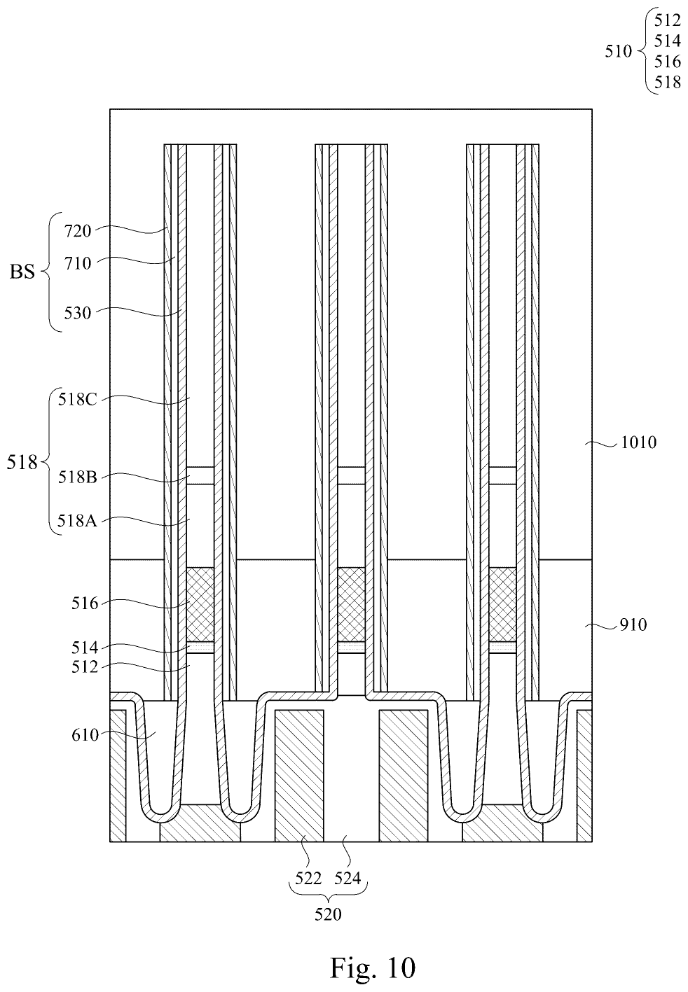

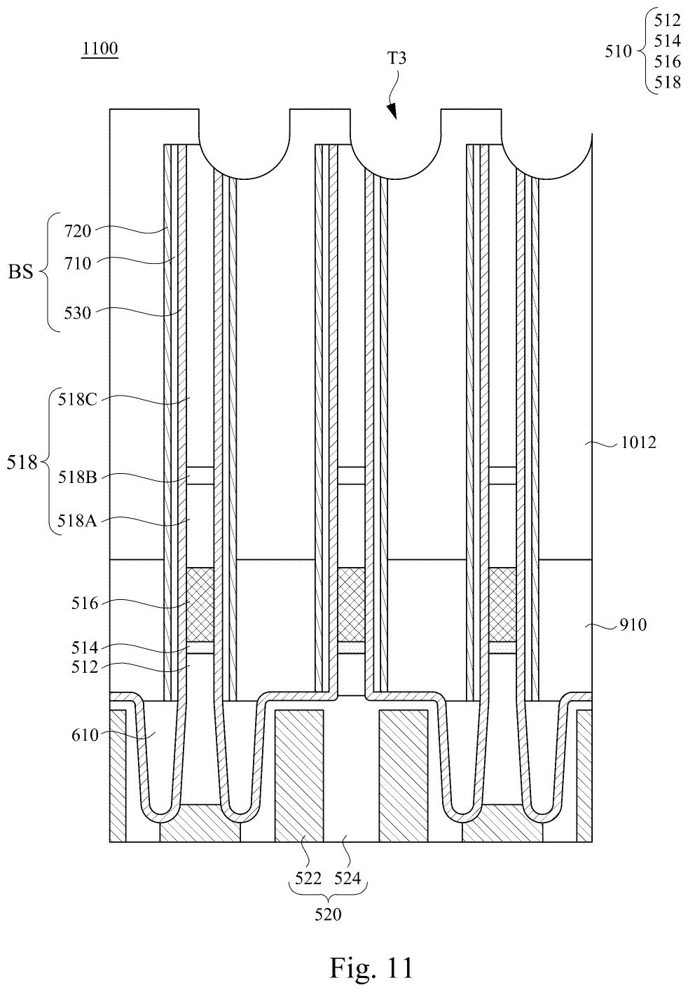

In operation 480, as shown in FIGS. 10-11, a plurality of landing pads 1012 is respectively formed on the conductive silicon layers 910 to form a semiconductor structure 1100. More specifically, as shown in FIG. 10, a conductive layer 1010 is formed to cover the bit-line structures 510, the bit-line spacers BS, and the conductive silicon layers 910. In some embodiments, the conductive layer 1010 is formed by CVD or physical vapor deposition (PVD). In some embodiments, the conductive layer 1010 is a metal layer including, such as, Co, Cu, Ni, Ru, Mn, Ag, Au, Pt, Fe, Mo, Rh, Ti, Ta, W, or combinations thereof. Next, as shown in FIG. 11, portions of the conductive layer 1010, the hard mask layers 518, and the bit-line spacers BS are etched to form a plurality trenches T3 by a wet etch or a dry etch. The conductive layer 1010 is separated by the trenches T3 to form the landing pads 1012.

Please still refer to FIG. 11. The semiconductor structure 1100 includes the semiconductor substrate 520, the bit-line structures 510, the bit-line spacers BS, the conductive silicon layers 910, and the landing pads 1012. The bit-line structures 510 are disposed on the semiconductor substrate 520. The bit-line spacers BS respectively cover the bit-line structures 510, in which each bit-line spacer BS includes the SiCO layer 530, the insulating oxide layer 710, and the insulating nitride layer 720. The SiCO layer 530 covers the bit-line structures 510. The insulating oxide layers 710 respectively cover the SiCO layer 530. The insulating nitride layers 720 respectively cover the insulating oxide layers 710. The oxygen concentration of the SiCO layer 530 is equal to or greater than 55 at %, and therefore the SiCO layer 530 can have a low dielectric constant. Moreover, since the SiCO layer 530 of present disclosure is formed under a high temperature, the SiCO layer 530 can also have a high density, which is beneficial to protect the bit-line structures 510 during the etching process. Furthermore, the SiCO layer 530 can have an ultra-thin thickness but the bit-line spacers BS can still have a low dielectric constant.

The following describes the features of the present disclosure more specifically with reference to Experimental Example 1. Although the following experimental examples are described, the materials, their amounts and ratios, processing details, processing procedures, etc., may be appropriately varied without exceeding the scope of the present disclosure. Accordingly, the present disclosure should not be interpreted restrictively by the experimental examples described below.

### Experimental Example 1: Preparation of SiCO Layers

The preparation conditions and properties of the SiCO layers of Example 1 and Comparative Example 1 are listed in the following Table 1. In Example 1, O₂ and 1,1,3,3-tetramethyldisiloxane were reacted under 550° C. by remote plasma-enhanced ALD to form a SiCO layer. The SiCO layer of Comparative Example 1 can be formed with a similar process under different experimental conditions.

TABLE 1

| | Example 1 | Comparative Example 1 |
|---|---|---|
| Temperature (° C.) | 550 | 400 |
| O₂ (sccm) | 115 | 32 |
| Oxygen concentration (at %) | 62.7 | 53.2 |
| Carbon concentration (at %) | 7.6 | 15.1 |
| Dielectric constant | 4.3 | 4.3 |
| Density (g/cm³) | 2.23 | 2.1 |
| Pinholes-free SiCO | 10 | 25 |
| thickness (angstrom) | | |

From the following Table 1, it can be known that since the SiCO layer of Example 1 is formed under the higher temperature by the O₂ with the higher flow rate, the SiCO layer of Example 1 has the higher density. Moreover, since the SiCO layer has the higher oxygen concentration and the lower carbon concentration, the SiCO layer of Example 1 has the lower dielectric constant. Furthermore, the SiCO layer of Example 1 can have the ultra-thin thickness without pinhole defects.

Based on the above, the present disclosure provides a semiconductor structure and a manufacturing method thereof. The semiconductor structure includes a bit-line structure and a bit-line spacer covering the bit-line structure, in which the bit-line spacer includes an oxygen-rich SiCO layer. The SiCO layer can have a thin thickness, a low dielectric constant, and a high density, which is beneficial to reduce the size of the semiconductor structure and reduce the RC delay.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A semiconductor structure, comprising:
a semiconductor substrate;
a bit-line structure disposed on the semiconductor substrate; and
a bit-line spacer covering the bit-line structure, wherein the bit-line spacer comprises:
a SiCO layer covering the bit-line structure, wherein an oxygen concentration of the SiCO layer is equal to or greater than 55 at %;
an insulating oxide layer covering the SiCO layer; and
an insulating nitride layer covering the insulating oxide layer.

2. The semiconductor structure of claim 1, wherein the oxygen concentration of the SiCO layer is from 55 at % to 65 at %.

3. The semiconductor structure of claim 1, wherein a carbon concentration of the SiCO layer is from 5 at % to 12 at %.

4. The semiconductor structure of claim 1, wherein the SiCO layer has a thickness of 8 angstrom to 15 angstrom.

5. The semiconductor structure of claim 1, wherein the SiCO layer has a dielectric constant of 3.9 to 4.7.

6. The semiconductor structure of claim 1, wherein the insulating oxide layer has a thickness of 3.5 angstrom to 5 angstrom.

7. The semiconductor structure of claim 1, wherein the SiCO layer conformally covers a sidewall of the bit-line structure.

8. The semiconductor structure of claim 1, wherein the bit-line structure comprises:
a conductive silicon layer;
a conductive layer disposed on the conductive silicon layer; and
a hard mask layer disposed on the conductive layer.

9. The semiconductor structure of claim 1, wherein the SiCO layer is in direct contact with the bit-line structure.

10. The semiconductor structure of claim 1, wherein the insulating oxide layer is a silicon dioxide layer, and the insulating nitride layer is a silicon nitride.

11. The semiconductor structure of claim 1, wherein a density of the SiCO layer is 2.2 g/cm³ to 2.5 g/cm³.

12. A method of manufacturing a semiconductor structure, the method comprising:
forming a bit-line structure on a semiconductor substrate;
forming a SiCO layer to cover the bit-line structure, wherein an oxygen concentration of the SiCO layer is equal to or greater than 55 at %;
forming an insulating oxide layer to cover the SiCO layer; and
forming an insulating nitride layer to cover the insulating oxide layer.

13. The method of claim 12, wherein forming the SiCO layer comprises reacting an oxygen gas and an alkyl siloxane to form the SiCO layer.

14. The method of claim 13, wherein a reaction temperature is 500° C. to 600° C.

15. The method of claim 13, wherein a flow rate of the oxygen gas is 75 sccm to 155 sccm.

16. The method of claim 13, wherein a flow rate of the alkyl siloxane is 54 sccm to 66 sccm.

17. The method of claim 13, wherein the alkyl siloxane comprises 1,1,3,3-tetramethyldisiloxane.

18. The method of claim 12, wherein forming the SiCO layer is performed by remote plasma-enhanced atomic layer deposition or plasma-enhanced chemical vapor deposition.

19. The method of claim 12, further comprising:
before forming the insulating oxide layer to cover the SiCO layer, forming a nitride layer to cover the SiCO layer and to fill a plurality of trenches in the semiconductor substrate and next to the bit-line structure; and
etching the nitride layer to expose a portion of the SiCO layer and leave portions of the nitride layer in the trenches by a wet etch solution.

20. The method of claim 19, wherein the wet etch solution comprises H₃PO₄, NH₄OH, H₂O₂, and H₂O.
